(19) United States
(12) Patent Application Publication
(10) Pub. No.: US 2024/0147754 A1
(43) Pub. Date: May 2, 2024

(54) Organic Electroluminescent Devices

(71) Applicant: Universal Display Corporation, Ewing, NJ (US)

(72) Inventors: Michael HACK, Carmel, CA (US); Michael S. WEAVER, Princeton, NJ (US)

(21) Appl. No.: 18/384,150

(22) Filed: Oct. 26, 2023

Related U.S. Application Data
(60) Provisional application No. 63/481,666, filed on Jan. 26, 2023.
(60) Provisional application No. 63/421,817, filed on Nov. 2, 2022.

(51) Int. Cl. H10K 50/19; H10K 50/82

(52) U.S. Cl. CPC H10K 50/19; H10K 50/82; H10K 2102/321

(57) ABSTRACT

A tandem device is provided that includes a non-inverted OLED arranged in a stack with an inverted OLED. A common electrode is disposed between the inverted OLED and the non-inverted OLED, which may be electrically addressable outside the OLED stack. The device includes one or more OLEDs and one or more inverted OLEDs in any desired arrangement and combination of inverted and non-inverted devices.

### CROSS-REFERENCE TO RELATED APPLICATIONS

This application claims the priority benefit of U.S. Provisional Application No. 63/421,817, filed Nov. 2, 2022 and U.S. Provisional Application No. 63/481,666, filed Jan. 26, 2023, the entire contents of each of which is incorporated herein by reference.

### FIELD

The present invention relates to organic emissive devices having inverted and non-inverted organic light emitting diode structures, and devices and techniques including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Alternatively the OLED can be designed to emit white light. In conventional liquid crystal displays emission from a white backlight is filtered using absorption filters to produce red, green and blue emission. The same technique can also be used with OLEDs. The white OLED can be either a single EML device or a stack structure. Color may be measured using CIE coordinates, which are well known to the art.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “red” layer, material, region, or device refers to one that emits light in the range of about 580-700 nm or having a highest peak in its emission spectrum in that region. Similarly, a “green” layer, material, region, or device refers to one that emits or has an emission spectrum with a peak wavelength in the range of about 500-600 nm; a “blue” layer, material, or device refers to one that emits or has an emission spectrum with a peak wavelength in the range of about 400-500 nm; and a “yellow” layer, material, region, or device refers to one that has an emission spectrum with a peak wavelength in the range of about 540-600 nm. In some arrangements, separate regions, layers, materials, regions, or devices may provide separate “deep blue” and a “light blue” light. As used herein, in arrangements that provide separate “light blue” and “deep blue”, the “deep blue” component refers to one having a peak emission wavelength that is at least about 4 nm less than the peak emission wavelength of the “light blue” component. Typically, a “light blue” component has a peak emission wavelength in the range of about 465-500 nm, and a “deep blue” component has a peak emission wavelength in the range of about 400-470 nm, though these ranges may vary for some configurations. Similarly, a color altering layer refers to a layer that converts or modifies another color of light to light having a wavelength as specified for that color. For example, a “red” color filter refers to a filter that results in light having a wavelength in the range of about 580-700 nm. In general, there are two classes of color altering layers: color filters that modify a spectrum by removing unwanted wavelengths of light, and color changing layers that convert photons of higher energy to lower energy. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373 l, 0.6245]; [0.6270, 0.3725]; |
| | Interior: [0.3 700, 0.4087]; [0.2886, 0.4572] |

More details on OLEDs, and the definitions described above, can be found in U.S. Pat. No. 7,279,704, which is incorporated herein by reference in its entirety.

### SUMMARY

According to an embodiment, an organic light emitting diode/device (OLED) is also provided. The OLED can include an anode, a cathode, and an organic layer, disposed between the anode and the cathode. According to an embodiment, the organic light emitting device is incorporated into one or more device selected from a consumer product, an electronic component module, and/or a lighting panel.

In an embodiment, an organic emissive device is provided that includes a substrate; a non-inverted organic light emitting device (OLED) disposed over the substrate; and an inverted OLED (IOLED) disposed over the substrate and arranged in a stack with the non-inverted OLED, separated by a common electrode from the non-inverted OLED. The device may include one or more inverted OLEDs and one or more non-inverted OLEDs. The common electrode may be a cathode or an anode, and the IOLED and OLED may be arranged such that the OLED or the IOLED is closer to the substrate, respectively. The outermost electrodes may be electrically connected so that the OLED and IOLED are electrically connected in parallel. During operation of the device, the voltage of the device as a whole may be not more than 120-150% of the voltage of the non-inverted OLED and/or the inverted OLED. The device may emit monochrome light, white light, or any desired spectrum. Each OLED and/or IOLED may include one or more emissive materials, including phosphorescent emitters, phosphor-sensitized fluorescent emitters, TADF emitters, and/or fluorescent emitters. The efficiency of the OLED and the IOLED may be within 10-20% of each other during operation. The device may include a backplane having a plurality of NMOS-type and/or PMOS-type transistors. The backplane may be either thin film or fabricated in a silicon wafer. The device may include other structures such as color altering layers, color filters, quantum dots, upconversion layers, downconversion layers, and the like, or any combination thereof. The device may be a consumer electronic device, such as a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, a sign, or combinations thereof.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows an example tandem device that includes a non-inverted OLED in series with an inverted OLED (IOLED) with a central electrode as disclosed herein.

FIG. 4 shows a schematic of layer alignment of a tandem OLED with a central cathode electrode connected to a contact patterned on the substrate as disclosed herein.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

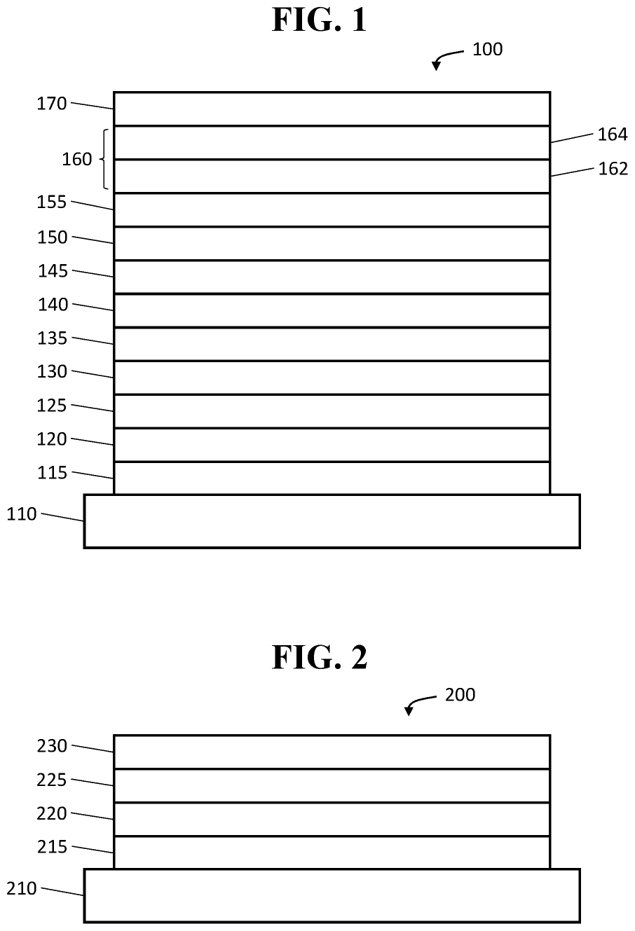

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. Barrier layer 170 may be a single- or multi-layer barrier and may cover or surround the other layers of the device. The barrier layer 170 may also surround the substrate 110, and/or it may be arranged between the substrate and the other layers of the device. The barrier also may be referred to as an encapsulant, encapsulation layer, protective layer, or permeation barrier, and typically provides protection against permeation by moisture, ambient air, and other similar materials through to the other layers of the device. Examples of barrier layer materials and structures are provided in U.S. Pat. Nos. 6,537,688, 6,597,111, 6,664,137, 6,835,950, 6,888,305, 6,888,307, 6,897,474, 7,187,119, and 7,683,534, each of which is incorporated by reference in its entirety.

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

In some embodiments disclosed herein, emissive layers or materials, such as emissive layer 135 and emissive layer 220 shown in FIGS. 1-2, respectively, may include quantum dots. An “emissive layer” or “emissive material” as disclosed herein may include an organic emissive material and/or an emissive material that contains quantum dots or equivalent structures, unless indicated to the contrary explicitly or by context according to the understanding of one of skill in the art. In general, an emissive layer includes emissive material within a host matrix. Such an emissive layer may include only a quantum dot material which converts light emitted by a separate emissive material or other emitter, or it may also include the separate emissive material or other emitter, or it may emit light itself directly from the application of an electric current. Similarly, a color altering layer, color filter, upconversion, or downconversion layer or structure may include a material containing quantum dots, though such layer may not be considered an “emissive layer” as disclosed herein. In general, an “emissive layer” or material is one that emits an initial light based on an injected electrical charge, where the initial light may be altered by another layer such as a color filter or other color altering layer that does not itself emit an initial light within the device, but may re-emit altered light of a different spectra content based upon absorption of the initial light emitted by the emissive layer and downconversion to a lower energy light emission. In some embodiments disclosed herein, the color altering layer, color filter, upconversion, and/or downconversion layer may be disposed outside of an OLED device, such as above or below an electrode of the OLED device.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a pluraility of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the thermal population between the triplet states and the singlet excited states. Compounds that are capable of generating E-type delayed fluorescence are required to have very small singlet-triplet gaps. Thermal energy can activate the transition from the triplet state back to the singlet state. This type of delayed fluorescence is also known as thermally activated delayed fluorescence (TADF). A distinctive feature of TADF is that the delayed component increases as temperature rises due to the increased thermal energy. If the reverse intersystem crossing rate is fast enough to minimize the non-radiative decay from the triplet state, the fraction of back populated singlet excited states can potentially reach 75%. The total singlet fraction can be 100%, far exceeding the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AES-T). Organic, non-metal containing, donor-acceptor luminescent materials may be able to achieve this. The emission in these materials is often characterized as a donor-acceptor charge-transfer (CT) type emission. The spatial separation of the HOMO and LUMO in these donor-acceptor type compounds often results in small AES-T. These states may involve CT states. Often, donor-acceptor luminescent materials are constructed by connecting an electron donor moiety such as amino- or carbazole-derivatives and an electron acceptor moiety such as N-containing six-membered aromatic ring.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments of the emissive region, the emissive region further comprises a host.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL:

A hole injecting/transporting material to be used in the present invention is not particularly limited, and any compound may be used as long as the compound is typically used as a hole injecting/transporting material.

### EBL:

An electron blocking layer (EBL) may be used to reduce the number of electrons and/or excitons that leave the emissive layer. The presence of such a blocking layer in a device may result in substantially higher efficiencies, and or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host:

The light emitting layer of the organic EL device of the present invention preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL:

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

Tandem OLED devices, i.e., those that include multiple discrete OLED structures within the device, typically arranged in a stack, are becoming more common as they allow for improved display brightness and lifetime. Current conventional tandem designs have a drive voltage that directly relates to the number of OLEDs in the device stack, which can increase the cost and complexity of the drive electronics. Additionally, current conventional tandem designs require the use of a charge generation layer (CGL) between adjacent OLEDs in the stack.

Embodiments disclosed herein provide a new structure for a tandem OLED in which the stack includes both an inverted OLED and a regular, non-inverted OLED. As used herein, an “inverted” OLED is one in which the cathode is closer to the primary supporting substrate than the anode of the same OLED structure, as previously shown and described with respect to FIG. 2. Conversely, a “non-inverted” or “regular” OLED is one in which the anode is closer to the primary supporting substrate, as shown in FIG. 1. In a device that includes both an inverted OLED and a non-inverted OLED as disclosed herein, the device voltage is the same or nearly the same as for a single-stack OLED (i.e., a device that includes only a single discrete OLED in the emissive stack), but the brightness and lifetime are similar to those of a tandem device. A two-device stacked tandem device as disclosed herein is based on a non-inverted OLED connected directly to an inverted OLED through a common central electrode.

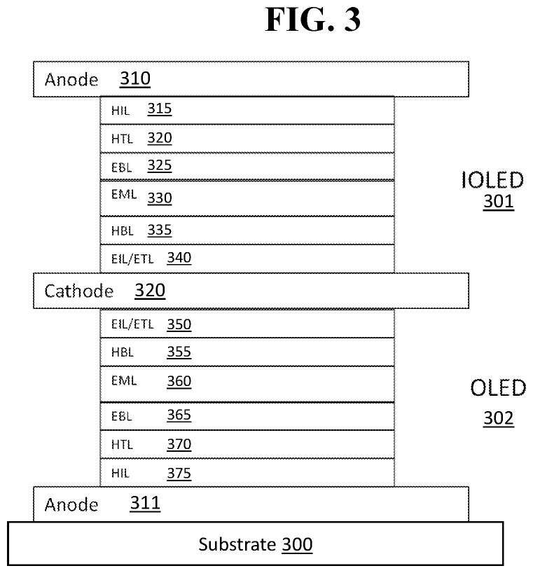

FIG. 3 shows an example configuration for the device based on a stack including two OLEDs, one inverted and one non-inverted. Additional OLED and/or IOLED devices also may be grown or otherwise deposited on the basic structure shown in FIG. 3. The inverted OLED may be grown, for example, on a cathode with an anode central electrode and a top OLED and top cathode.

The device in FIG. 3 includes an inverted OLED 301 and a non-inverted OLED 302. A common cathode 320 is disposed between the two devices and, as used herein, is considered to be part of each device. That is, the inverted OLED 301 may be described as including or being defined by the anode 310 and the common cathode 320, and the non-inverted OLED 302 may be described as including or being defined by the common cathode 320 and the anode 311. The entire device is disposed over a substrate 300, and may be grown or otherwise deposited on the substrate 300 during fabrication. In the inverted OLED 301, the common cathode 320 is closer to the substrate than the anode 310; in the non-inverted OLED 302, the anode 311 is closer to the substrate 300 than the common cathode 320. The inverted OLED 301 includes the anode 310, common cathode 320, and all layers shown between them 315-340; similarly, the non-inverted OLED 302 includes the common cathode 320, the individual anode 311, and all layers between them 350-375.

Each of the OLEDs 301, 302 may include some, any, or all of the layers typically used in an OLED stack. In the example shown in FIG. 3, each device includes the following layers as shown:
hole injection layers 315, 375
hole transport layers 320, 370
electron blocking layers 325, 365
emissive layers 330, 360
hole blocking layers 335, 355
electron injection and/or transport layers 340, 350

More generally, any non-inverted OLED or inverted OLED in a device as disclosed herein may include any of the layers shown and described with respect to FIG. 1, including any of the materials, combinations, arrangements, and the like as are known for OLED structures in the art. Notably, the layers in each OLED are arranged relative to the common cathode and each separate anode as would be expected for a separate device. For example, the electron injection/transport layer or layers 340, 350 are disposed close to the common cathode 320, while the hole injection and transport layers are disposed farther away from the common cathode 320 and close to each respective anode 310, 311. Similarly, electron transport layers 340, 350 may be disposed closer to the common cathode 320 than each of the corresponding emissive layers 330, 360, respectively. In an arrangement in which the common electrode 320 is an anode, the opposite arrangement may be used so that the electron transport layers 340, 350 are disposed farther away from the common anode than the corresponding emissive layers 330, 360, respectively. Hole transport layers 320, 370 may be arranged closer to a common anode than the corresponding emissive layers 330, 360, respectively, when a common anode is used (i.e., the inverse of the arrangement in FIG. 3); or the hole transport layers 320, 370 may be disposed farther away from a common cathode 320 as shown in FIG. 3.

The example device in FIG. 3 includes two external anode connections for anodes 310, 311 and one external cathode connection for the common cathode 320. In this context, the term “external” refers to a connection that extends outside of the OLED stack and is directly connected to the associated electrode. Patterning techniques such as photolithography (eLeap) or other techniques may be used to make electrical connections to the central electrode 320.

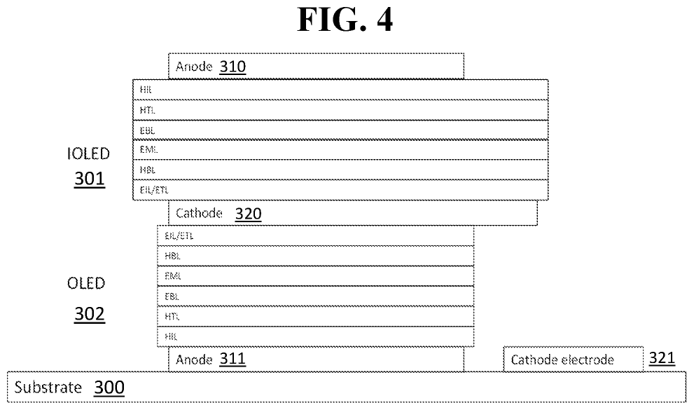

FIG. 4 shows a similar device with a different fabrication and patterning approach, in which external connections to the lower anode 311 and the common cathode 320 are patterned on the substrate 300. In this configuration, the organic layers in the lower OLED 302 may be deposited through a mask over the anode 311 and extend beyond the anode such that the deposited cathode does not short directly to the anode. The common cathode 320 is then deposited such that it also connects to the patterned cathode electrode 321 on the substrate 300. Finally the organic layers in the top OLED 301 and the top anode 310 are deposited. The emissive layers (EMLs) may be deposited with, for example, a fine metal mask to define different color subpixels. FIG. 4 also shows an exaggerated view of a configuration of relative staggered positioning of the various layers in the OLEDs 301, 302 to allow for electrical connections and the like.

Although the example arrangements shown in FIGS. 3-4 use a common cathode between the OLED and the inverted OLED, in other embodiments the relative position of the OLED and inverted OLED may be exchanged, such that a common anode is used instead of a common cathode. In such an embodiment, outer cathodes may be used to match the example common cathode, instead of the anodes 310, 311. Accordingly, devices disclosed herein may be described as including adjacent OLED/IOLED pairs separated by a common anode or cathode, where the common anode or cathode is considered a part of each of the OLED and IOLED as previously disclosed. In an arrangement as shown in FIG. 3, the common anode or cathode may be externally addressable relative to the stack. That is, the common anode or cathode may have a direct electrical connection that extends out of the organic emissive stack.

In some embodiments, the outer electrodes 310, 311 (regardless of whether they are anodes or cathodes) may be electrically connected to one another, such that the inverted OLED 301 and the non-inverted OLED 302 are electrically arranged in parallel. In such a configuration, the OLED and IOLED may exhibit the same or similar voltage during operation, while the entire device as a whole has a voltage that is not more than 120-150% of the voltage of either device for the same drive current. In contrast, a similar conventional tandem device would require twice the voltage (200%) of either individual OLED/IOLED device when operated at the same current and luminance.

The device structures shown in FIGS. 3-4 are scalable, in that the non-inverted OLED and/or the inverted OLED may themselves be formed of a tandem stack architecture including two or more OLED structures. In such a configuration the tandem stacks in each OLED structure may be separated by charge generating layers instead of addressable electrodes as used between the OLED and IOLED in the primary structure disclosed herein.

Furthermore, the architecture may be scaled to include more than one OLED/IOLED pair, or an uneven number of individual OLED and IOLED devices, or any combination of any number of OLED and IOLED stacks separated by common electrodes, such as the common cathode 320 shown in FIGS. 3-4. That is, a device as disclosed herein may have the basic OLED/IOLED structure(s) shown in FIGS. 3 and/or 4 repeated, such that it has one or more non-inverted OLEDs and/or one or more inverted OLEDs, each separated from the other(s) by an electrode as shown. In some embodiments, a device as disclosed herein may be described as including m non-inverted OLEDs and n inverted OLEDs, and wherein m≥1 or 2 and/or n≥1 or 2, i.e., any number of OLEDs and IOLEDs. In such an arrangement, the 120-150% voltage limit on individual devices in parallel, as previously described, may not apply. Regardless of the number of OLED and/or IOLED devices in the stack, they may be arranged in a variety of configurations. In some embodiments, it may be preferred to use an alternating arrangement in which each OLED has a common cathode or anode with an inverted OLED and each inverted OLED has a common cathode or anode with an adjacent OLED. The stack also may be arranged such that a non-inverted OLED 302 is closest to the substrate, as shown in FIGS. 3-4, or such that an inverted OLED is arranged closest to the substrate, in which case the common central electrode may be an anode as previously disclosed.

Each layer shown in FIGS. 3 and 4 may have the same properties, material(s), and arrangements as previously disclosed, including the emissive layers, the non-emissive organic layers, and the electrode layers. For example, each emissive layer 330, 360 may use any combination of host(s) and/or emitter dopant(s) as known in the art. The OLED 302 and IOLED 301 may use the same emissive material or materials as each other, or each may use one or more different emitter and/or host materials. The emissive layers of each device 301, 302 may be configured to emit the same color light, or they may emit different colors of light, including emission in the near infra-red and/or ultra-violet regions of the spectrum. Each emissive layer 330, 360 may include one or more phosphorescent emitters, phosphor-sensitized fluorescent emitters, thermally-activated delayed fluorescence (TADF) emitters, and/or fluorescent emitters. The common electrode 320 may be transparent or semi-transparent as is known for electrodes in the art. The common electrode may be organic, inorganic, or a combination thereof.

Other structures used in tandem or individual OLEDs may be used in the stacked device structure disclosed herein. For example, various color-altering layers and devices may be used to tune the color of light emitted by the stack as a whole or by one device within the stack. Such devices may include color filters, color altering layers, cavity arrangements, quantum dots, upconversion layers or structures, downconversion layers or structures, or the like, or any combination thereof.

A device as disclosed herein may be configured to emit monochrome light, such that 95-100% of emitted light (based on emitted power) is within 40 nm, 50 nm, or 60 nm of a central peak, or where all emitted light has CIE coordinates within (±0.02, ±0.02) of a centroid CIE value. Alternatively, the device may be constructed and arranged to emit white or “full spectrum” visible light, or any desired spectrum including visible, near infra-red, and/or near ultra-violet light.

The device may be top emitting, bottom emitting, transparent, or bi-directional, depending on the conductive materials used for the various electrodes 310, 311, 320. The electrodes 310, 320 may be transparent, semi-transparent, or opaque, and maybe organic, inorganic, or any combination thereof. The device also may include a backplane that incorporates multiple NMOS- and/or PMOS-type MOSFETs, for example thin film transistors based on amorphous silicon, poly-Si, organic transistors, oxide transistors, carbon nanotube based TFTs or else driven by single crystal silicon transistors from a silicon wafer, or microIC arrangements placed on a substrate to drive the OLED device.

The device may be constructed such that the OLED and IOLED have the same efficiency or different efficiencies. In some embodiments it may be desirable for the OLED and IOLED to have efficiencies within 10%, 15%, or 20% of each other. For example, it may be beneficial for the OLED and the IOLED to have similar characteristics such that, when connected in parallel, at the same drive voltage they would have similar currents and light output. Such an arrangement is not necessary in arrangements where the OLED and IOLED are driven independently.

In some embodiments, an OLED or IOLED as disclosed herein can contain one or more compounds that can be used as a phosphorescent sensitizer, for example, in an emissive layer or other layer of the OLED or IOLED as previously disclosed. In such a device, one or multiple layers in the OLED or IOLED contains an acceptor in the form of one or more fluorescent and/or delayed fluorescence emitters. In some embodiments, the compound can be used as one component of an exciplex to be used as a sensitizer. As a phosphorescent sensitizer, the compound must be capable of energy transfer to the acceptor and the acceptor will emit the energy or further transfer energy to a final emitter. The acceptor concentrations can range from 0.001% to 100%. The acceptor could be in either the same layer as the phosphorescent sensitizer or in one or more different layers. In some embodiments, the acceptor is a TADF emitter. In some embodiments, the acceptor is a fluorescent emitter. In some embodiments, the emission can arise from any or all of the sensitizer, acceptor, and final emitter.

Additionally, in some embodiments, an emissive region may have one or more emissive layer. In an embodiment, the number of layers in each emissive region of each device (i.e., OLED or IOLED) may be the same. In alternative embodiment, the number of layers in each emissive region of each device may be different. In yet another alternative embodiment, the number of layers in some emissive regions of each device may be the same and some emissive regions of each device may be different. In some embodiments, an emissive layer of the one or more emissive layers of any emissive region may comprise a phosphorescent material, a fluorescent material or any combination thereof. In some embodiments, the emissive regions in the OLED or IOLED may comprise a sensitizer and an acceptor with various sensitizing device characteristics disclosed in this application.

Embodiments disclosed herein may provide measurable benefits in comparison to a conventional device, especially a conventional tandem device that uses exclusively stacked non-inverted OLEDs or exclusively stacked inverted OLEDs. For example, a device as disclosed herein may provide the same luminance, efficiency, and/or lifetime results as a conventional tandem device having the same number of distinct OLED structures in the stack (and typically separated by CGLs as opposed to externally-addressable electrodes). However, the device may operate at the same voltage as a single (unstacked) device when using an even number of devices in the stack. Structures disclosed herein also may be used to provide a device with three or more OLED/IOLED devices in a single stack, but without requiring the use of CGLs between adjacent devices as in conventional tandem devices.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. An organic emissive device comprising:
a substrate;
a first non-inverted organic light emitting device (OLED) disposed over the substrate;
a first inverted OLED disposed over the substrate and arranged in a stack with the first non-inverted OLED;
wherein the first inverted OLED and the first non-inverted OLED have a common anode or a common cathode disposed between the first non-inverted OLED and the first inverted OLED.

2. The organic emissive device of claim 1, wherein the device comprises a plurality of non-inverted OLEDs.

3. The organic emissive device of claim 1, wherein each non-inverted OLED in the organic emissive device has a common anode or a common cathode disposed between the each non-inverted OLED and an adjacent inverted OLED in the organic emissive device.

4. The organic emissive device of claim 2, wherein the device comprises a plurality of inverted OLEDs.

5. The organic emissive device of claim 4, wherein each inverted OLED in the organic emissive device has a common anode or a common cathode disposed between the each inverted OLED and an adjacent non-inverted OLED in the organic emissive device.

6. The organic emissive device of claim 1, wherein the device comprises a plurality of inverted OLEDs.

7. The organic emissive device of claim 6, wherein each inverted OLED in the organic emissive device has a common anode or a common cathode disposed between the each inverted OLED and an adjacent non-inverted OLED in the organic emissive device.

8. The organic emissive device of claim 1, wherein the device comprises m non-inverted OLEDs and n inverted OLEDs, and wherein m≥2 and/or n≥2.

9. The organic emissive device of claim 1, wherein the common anode or cathode disposed between the first non-inverted OLED and the first inverted OLED is transparent.

10. The organic emissive device of claim 1, wherein the common anode or cathode disposed between the first non-inverted OLED and the first inverted OLED is externally addressable.

11. The organic emissive device of claim 10, wherein two outermost electrodes of the device are electrically connected to one another so that the first non-inverted OLED and the first inverted OLED are electrically arranged in parallel with each other.

12. The organic emissive device of claim 10, wherein, during operation of the device, the voltage of the organic emissive device is not more than 120-150% of the voltage of the first non-inverted OLED or the first inverted OLED.

13. The organic emissive device of claim 1, wherein the first non-inverted OLED is closer to the substrate than the first inverted OLED.

14. The organic emissive device of claim 1, wherein the first inverted OLED is closer to the substrate than the first non-inverted OLED.

15. The organic emissive device of claim 1, wherein the device emits monochrome light.

16. The organic emissive device of claim 1, wherein:
the first non-inverted OLED comprises a first emissive material;
the first inverted OLED comprises a second emissive material; and
the first emissive material is different than the second emissive material.

17. The organic emissive device of claim 16, wherein each of the first and second emissive materials are independently selected from a group consisting of: a phosphorescent emitter, a phosphor-sensitized fluorescent emitter, a thermally-activated delayed fluorescence (TADF) emitter, and a fluorescent emitter.

18. The organic emissive device of claim 1, wherein:
the first non-inverted OLED comprises a first emissive material;
the first inverted OLED comprises a second emissive material; and
the first emissive material is the same as the second emissive material.

19-28. (canceled)

29. A consumer electronic device comprising:
a device comprising:
a substrate;
a first non-inverted organic light emitting device (OLED) disposed over the substrate;
a first inverted OLED disposed over the substrate and arranged in a stack with the first non-inverted OLED; and
wherein the first inverted OLED and the first non-inverted OLED have a common anode or a common cathode disposed between the first non-inverted OLED and the first inverted OLED.

30. The consumer electronic device of claim 29, wherein the device is at least one type selected from the group consisting of: a flat panel display, a curved display, a computer monitor, a medical monitor, a television, a billboard, a light for interior or exterior illumination and/or signaling, a heads-up display, a fully or partially transparent display, a flexible display, a rollable display, a foldable display, a stretchable display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video walls comprising multiple displays tiled together, a theater or stadium screen, and a sign.
